(19) United States
(12) Patent Application Publication
(10) Pub. No.: US 2008/0116585 A1
(43) Pub. Date: May 22, 2008

(54) MULTI-CHIP STRUCTURE

(75) Inventor: Chi-Hsing Hsu, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/624,512

(22) Filed: Jan. 18, 2007

(30) Foreign Application Priority Data
Nov. 16, 2006 (TW) 95142396

(51) Int. Cl. H01L 23/538

(52) U.S. Cl. 257/777; 257/E23.169

(57) ABSTRACT

A multi-chip structure including a first chip and a second chip is provided. The first chip has a buffer area, an interconnection area, and a first surface. The buffer area is electrically insulated from the interconnection area. The second chip is disposed on the first surface. The second chip is electrically connected to the interconnection area and the buffer area. A first kind of signal and a second kind of signal can be output from the second chip. The first kind of signal is input into the interconnection area to participate in the processing operation in the first chip. The second kind of signal is input into the buffer area.

### CROSS-REFERENCE TO RELATED APPLICATION

This application claims the priority benefit of Taiwan application serial no. 95142396, filed on Nov. 16, 2006. All disclosure of the Taiwan application is incorporated herein by reference.

### BACKGROUND OF THE INVENTION

1. Field of the Invention

The present invention relates to a semiconductor device, and more particularly to a multi-chip structure.

2. Description of Related Art

In the semiconductor industry, the production of integrated circuits (IC) can be divided into three major stages: the designing of the IC, the processing of the IC and the packaging of the IC.

In the processing of the IC, the steps for fabricating a chip include wafer production, IC formation and wafer sawing. The wafer has an active surface, the surface of the wafer where the active elements are disposed. After the fabrication of the integrated circuits in the wafer is complete, a plurality of bonding pads is disposed on the active surface of the wafer. Hence, each chip cut out from the wafer may be electrically connected to a carrier through the bonding pads. The carrier is a leadframe or a package substrate, for example. The chip is electrically connected to the carrier by wire-bonding or flip-chip bonding so that the bonding pads on the chip can be electrically connected to the contacts of the carrier to produce a chip package structure.

When the flip-chip bonding technology is used, a bump is formed on each bonding pad for electrically connecting with an external package substrate after bonding pads are formed on the active surface of the wafer. Because the bumps are normally arranged as an area array on the active surface of the chip, the flip-chip bonding technology is particularly suitable for applying to a chip package structure with high contact count and high contact density, for example, the flip-chip ball grid array package now commonly adopted by the semiconductor packaging industry. Moreover, the bumps can provide a shorter transmission path between the chip and the carrier, so the flip-chip bonding technology compared with the wire-bonding technology can boost the electrical performance of the chip package.

However, with the ever-increasing demands for better electrical performance, lower production cost and higher level of integration, the foregoing chip package structure having single chip can no longer completely satisfy the requirements of the electronics industry. In an attempt to resolve the problem, two different methods have been developed. The first method aims to integrate all the core functions into a single chip. In other words, digital logic, memory and analog functions are completely integrated into a single chip in the so-called system-on-chip concept. Consequently, the system-on-chip can provide more complex functions than a conventional single chip. Yet, the system-on-chip requires too many masking steps. Moreover, its production cost is high but its yield is low. Therefore, the development of the system-on-chip concept has encountered some considerable barriers. The second method involves forming a multi-chip package by stacking a number of chips and connecting the chips using wire-bonding or flip-chip bonding technology.

### SUMMARY OF THE INVENTION

Accordingly, the present invention is directed to a multi-chip structure with higher processing yield and lower production cost.

As embodied and broadly described herein, the invention provides a multi-chip structure including a first chip, a second chip and a plurality of conductive bumps. The first chip has a buffer area, an interconnection area, a redistribution conductive area and a first surface. The buffer area is electrically insulated from the interconnection area and the redistribution conductive area is disposed on the first surface. The second chip is also disposed on the first surface. The conductive bumps are disposed between the first chip and the second chip. The second chip is electrically connected to the interconnection area through a portion of the conductive bumps. Furthermore, the second chip is electrically connected to the buffer area through another portion of the conductive bumps and the redistribution conductive area.

The present invention also provides a multi-chip structure including a first chip, a second chip and an electrical connection module. The first chip has a buffer area, an interconnection area and a first surface. The buffer area is electrically insulated from the interconnection area and the second chip is disposed on the first surface. The electrical connection module is disposed on the first chip and the second chip. The second chip is electrically connected to the interconnection area through a portion of the electrical connection module. The second chip is also electrically connected to the buffer area through another portion of the electrical connection module.

The present invention also provides a multi-chip structure including a first chip and a second chip. The first chip has a buffer area, an interconnection area and a first surface. The buffer area is electrically insulated from the interconnection area. The second chip is disposed on the first surface. The second chip is electrically connected to the interconnection area and the buffer area, respectively. The second chip outputs a first kind of signal and a second kind of signal. The first kind of signal is input into the interconnection area to participate in the data processing operation in the first chip. The second kind of signal is input into the buffer area.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic side cross-sectional view of a multi-chip structure according to a first embodiment of the present invention.

FIG. 1B is a schematic top view of the multi-chip structure shown in FIG. 1A.

FIG. 2A is a schematic side cross-sectional view of a multi-chip structure according to a second embodiment of the present invention.

FIG. 2B is a schematic top view of the multi-chip structure shown in FIG. 2A.

FIG. 3 is a schematic side cross-sectional view of a multi-chip structure according to a third embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

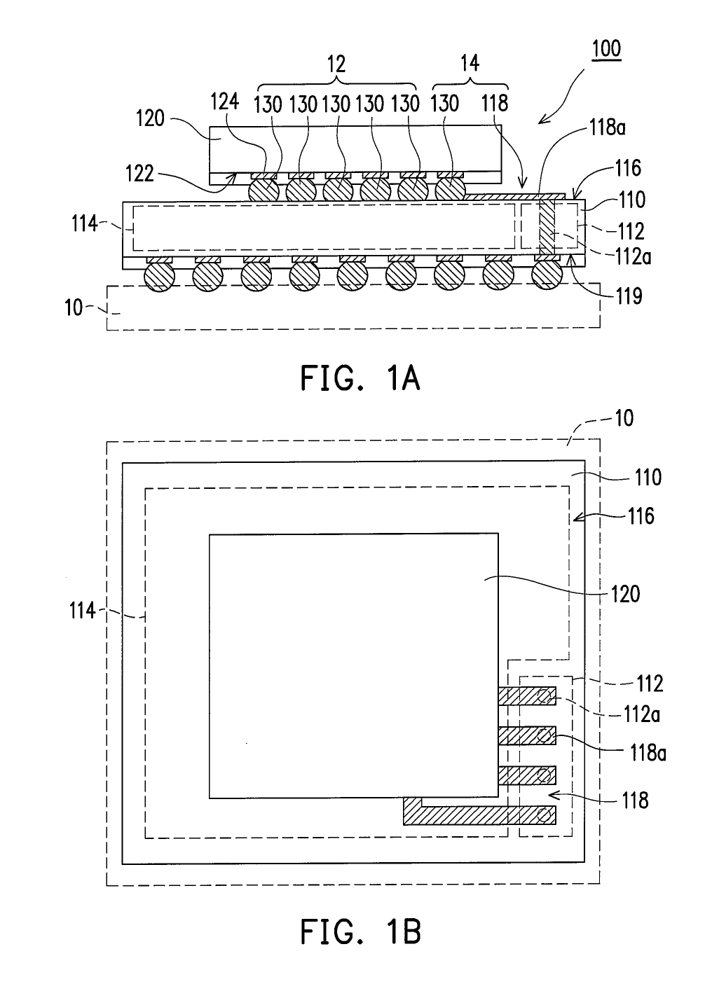

FIG. 1A is a schematic side cross-sectional view of a multi-chip structure according to a first embodiment of the present invention. FIG. 1B is a schematic top view of the multi-chip structure shown in FIG. 1A. As shown in FIGS. 1A and 1B, the multi-chip structure 100 in the first embodiment includes a chip 110 (for example, a North Bridge chip or a South Bridge chip) and a chip 120 (for example, a central processing unit). It should be noted that the first embodiment and the subsequent embodiments are described by using a multi-chip structure with, for example, two chips. The multi-chip structure 100 may be disposed on an electronic device 10 (for example, a package substrate, a printed circuit board or another chip) that is below the multi-chip structure 100.

The chip 110 has a buffer area 112, an interconnection area 114 and a surface 116. The buffer area 112 is electrically insulated from the interconnection area 114. In other words, there are no other trace lines inside the chip 110 for electrically connecting the buffer area 112 to the interconnection area 114. The chip 120 is disposed on the surface 116. The chip 120 is electrically connected to the interconnection area 114 and the buffer area 112 respectively. The chip 120 outputs a first kind of signal and a second kind of signal. Furthermore, the first kind of signal is input into the interconnection area 114 to participate in the data processing operation in the chip 110, and the second kind of signal is input into the buffer area 112.

More specifically, the interconnection area 114 is the area of the chip 110 for executing the data processing function. Therefore, a plurality of semiconductor devices and metal lines (not shown) are disposed inside the interconnection area 114. On the other hand, the buffer area 112 has no semiconductor devices disposed therein. The buffer area 112 is not related to the data processing function of the chip 110 and simply serves as a bridge for electrically connecting the chip 110 with the electronic device 10 that is below the multi-chip structure 100. The chip 120 is disposed on the chip 110. The chip 120 outputs the first kind of signal and the second kind of signal. The first kind of signal will not be transmitted to the electronic device 10 through the buffer area 112 of the chip 110. The second kind of signal will be transmitted to the electronic device 10 only through the buffer area 112 of the chip 110.

An electrical connection member 12 is disposed between the chip 110 and the chip 120. The electrical connection member 12 electrically connects the interconnection area 114 of the chip 110 to the chip 120. The first kind of signal of the chip 120 is transmitted to the interconnection area 114 of the chip 110 through the electrical connection member 12. It should be noted that the electrical connection member 12 may transmit the signal of the chip 110 back to the chip 120 so that the chip 120 can perform further data processing. An electrical connection member 14 is also disposed between the chip 110 and the chip 120. The electrical connection member 14 electrically connects the buffer area 112 of the chip 110 to the chip 120. The second kind of signal of the chip 120 is transmitted to the electronic device 10 through the electrical connection member 14. In addition, the second kind of signal is not used for the chip 110 to do any data processing procedures.

In other words, the conveyance of electrical signals between the chip 120 and the interconnection area 114 of the chip 110 normally indicates that the chip 120 and the chip 110 are in a mutual communication state or in a one-way signal transmission state. In general, the conveyance of electrical signals between the chip 120 and the interconnection area 114 demands a coordinating data processing between the chip 120 and the chip 110. Thereafter, the multi-chip structure 100 transmits these electrical signals to the electronic device 10 electrically connected to the chip 110.

However, the conveyance of electrical signals between the chip 120 and the buffer area 112 of the chip 110 normally indicates that the chip 120 and the electronic device 10 are in a direct mutual communication state or in a direct one-way signal transmission state. The conveyance of electrical signals between the chip 120 and the buffer area 112 usually only requires the independent data processing of the chip 120 and does not requires the data processing of the chip 110. Thereafter, the chip 120 transmits these electrical signals to the electronic device 10 through the buffer area 112. The buffer area 112 only serves as a medium for conveying electrical signals and does not perform any data processing. Thus, the interface of the multi-chip structure 100 for transmitting electrical signals to the electronic device 10 is enhanced and its operating efficiency is increased.

Furthermore, the multi-chip structure 100 in the first embodiment further includes a plurality of conductive bumps 130 disposed between the surface 116 of the chip 110 and the chip 120. The chip 110 further includes a redistribution conductive area 118 on the surface 116. The chip 120 is electrically connected to the interconnection area 114 through a portion of the conductive bumps 130 (that is, the electrical connection member 12). Moreover, the chip 120 may be electrically connected to the buffer area 112 through another portion of the conductive bumps 130 and the redistribution conductive area 118 (that is, in general terms, the electrical connection member 14).

The material forming the conductive bumps 130 may include a single metal element or an alloy. The material may be a lead-containing material (for example, lead or lead-tin alloy) or a lead-free material. The lead-free material may include gold, copper, tin or nickel, and it may also include an alloy or compound of gold, copper, tin or nickel.

It should be noted that the buffer area 112 in the first embodiment includes a plurality of conductive through holes 112a. Furthermore, these conductive through holes 112a extends from the surface 116 to the another surface 119 (generally, the active surface) of the chip 110. The surface 116 and the surface 119 are opposite to each other. In addition, the redistribution conductive area 118 includes a plurality of redistribution conductive traces 118a. Moreover, the chip 120 may have a surface 122 (generally, an active surface) and a plurality of bonding pads 124 disposed thereon. One end of each conductive through hole 112a on the surface 116 may electrically connect to one of the bonding pads 124 sequentially through one of the redistribution conductive traces 118a and one of the conductive bumps 130. Therefore, a portion of the boding pads 124 of the chip 120 may directly transmit electrical signals to the electronic device 10 sequentially through a portion of the conductive bumps 130, the redistribution conductive traces 118a and the conductive through holes 112a.

Obviously, the structure and external form of the electrical connection member responsible for transmitting the first kind of signal and the electrical connection member responsible for transmitting the second kind of signal may be modified according to the actual requirements of the designer. The foregoing embodiment is used only as an example and hence should not be used to limit the present invention. In the following, other structures and external forms of the electrical connection member are described.

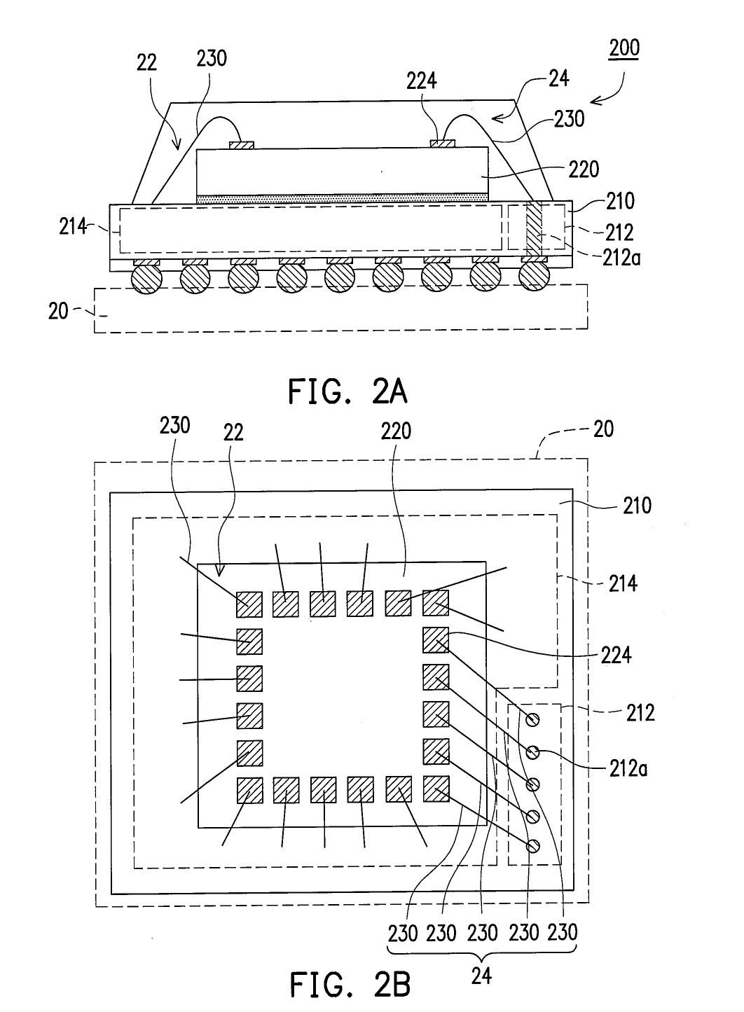

FIG. 2A is a schematic side cross-sectional view of a multi-chip structure according to a second embodiment of the present invention. FIG. 2B is a schematic top view of the multi-chip structure shown in FIG. 2A. For example, as shown in FIGS. 2A and 2B, the chip 220 in the multi-chip structure 200 of the second embodiment is electrically connected to the chip 210 through a plurality of bonding wires 230. It should be noted that the operating mode of the multi-chip structure 200 and its operating mode with the electronic device 20 that is below the multi-chip structure 200 in the second embodiment are very similar to that of the multi-chip structure 100 in the first embodiment. The multi-chip structure 200 in the second embodiment and the multi-chip structure 100 in the first embodiment have a structural variation mainly.

The chip 220 is electrically connected to the interconnection area 214 of the chip 210 through a portion of the bonding wires 230 (that is, the electrical connection member 22 for transmitting the first kind of signal). Furthermore, the chip 220 is electrically connected to the buffer area 212 of the chip 210 through another portion of the bonding wires 230 (that is, the electrical connection member 24) for transmitting the second kind of signal). In addition, the material forming the bonding wires 230 includes gold.

It should be noted that the chip 210 in the second embodiment generally does not use the setup of the redistribution conductive area 118 (shown in FIG. 1B). This is because a portion of the bonding wires 230 (the electrical connection member 22) may be directly electrically connected to a portion of the bonding pads 224 of the chip 220 and the conductive through holes 212a of the buffer area 212. Therefore, a portion of the bonding pads 224 of the chip 220 may directly transmit electrical signals to the electronic device 20 that is below the multi-chip structure 200 sequentially through a portion of the bonding wires 230 and the conductive through holes 212a.

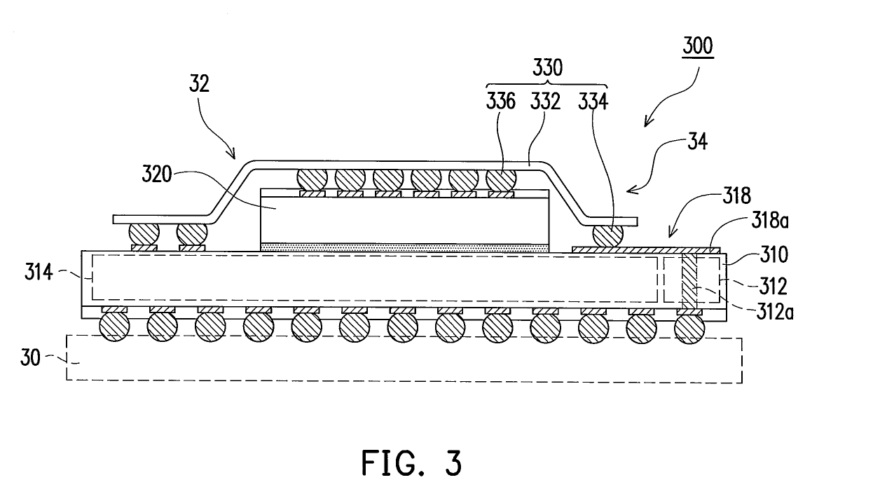

FIG. 3 is a schematic side cross-sectional view of a multi-chip structure according to a third embodiment of the present invention. For example, as shown in FIG. 3, the multi-chip structure 300 in the third embodiment further includes an electrical connection module 330 comprising a flexible circuit board 332, a plurality of conductive bumps 334 and a plurality of conductive bumps 336. The flexible circuit board 332 is disposed on the chip 310 and the chip 320. The conductive bumps 334 are disposed between the chip 310 and the flexible circuit board 332, and the conductive bumps 336 are disposed between the chip 320 and the flexible circuit board 332. The chip 320 may be electrically connected to the interconnection area 314 of the chip 310 sequentially through a portion of the conductive bumps 336, a portion of the flexible circuit board 332 and a portion of the conductive bumps 334. On the whole, the foregoing portion of the conductive bumps 336, portion of the flexible circuit board 332 and portion of the conductive bumps 334 are the electrical connection member 32 for transmitting the first kind of signal.

In addition, the chip 320 may be electrically connected to the buffer area 312 of the chip 310 sequentially through another portion of the conductive bumps 336, another portion of the flexible circuit board 332, another portion of the conductive bumps 334 and the redistribution conductive traces 318a in the redistribution conductive area 318. On the whole, the aforementioned another portion of the conductive bumps 336, another portion of the flexible circuit board 332, another portion of the conductive bumps 334 and the redistribution conductive traces 318a in the redistribution conductive area 318 are the electrical connection member 34 for transmitting the second kind of signal. In other words, in the third embodiment, a portion of the bonding pads 324 of the chip 320 may directly transmit electrical signals to the electronic device 30 that is below the multi-chip structure 300 sequentially through a portion of the conductive bumps 336, a portion of the flexible circuit board 332, a portion of the conductive bumps 334, the redistribution conductive traces 318a in the redistribution conductive area 318 and the conductive through holes 312a in the buffer area 312.

It should be noted that the designer might modify the range of coverage of the flexible circuit board 332 over the chip 310 and the chip 320 according to the design requirements. Therefore, if the flexible circuit board 332 is wide enough to cover the conductive through holes 312a in the buffer area 312, then the designer may do away with the setting of the redistribution conductive area 318. Thus, the flexible circuit board 332 may be directly electrically connected to the conductive through holes 312a through a portion of the conductive bumps 334. In other words, the chip 320 may be electrically connected to the buffer area 312 of the chip 310 sequentially through a portion of the conductive bumps 336, the flexible circuit board 332 and a portion of the conductive bumps 334. However, the foregoing conditions are not shown in the figure.

It should be noted that the operating mode of the multi-chip structure 300 and its operating mode with the electronic device 30 in the third embodiment are similar to that of the multi-chip structure 100 and that of the multi-chip structure 200 in the foregoing embodiments. The multi-chip structure 300 of the third embodiment and the multi-chip structures 100, 200 of the previous embodiments have a structural variation.

In the embodiments of the present invention, the chips 110, 210, 310 may be North Bridge chips, the chips 120, 220, 320 may be central processing units, and the electronic devices 10, 20, 30 may be motherboards. The basic concept of outputting the first and the second kind of signal from the chip (120, 220 or 320) in an embodiment that involves the central processing unit and the North Bridge chip is as follows. First, the first kind of signal is the exchange signal between the central processing unit and the North Bridge chip, and a portion of the first kind of signal may be used to communicate and connect with the graphic chip of the North Bridge chip. On the other hand, the second kind of signal may be the signal of the central processing unit used for communicating with the memory on the motherboard. The second kind of signal will be transmitted to the memory on the motherboard without passing through the circuits of the North Bridge chip.

In a conventional computer system, the central processing unit, the North Bridge chip and the memory are respectively disposed on the motherboard. The central processing unit transmits signals to the North Bridge chip and the memory through circuits on the motherboard. According to the embodiment of the present invention, a multi-chip structure comprising a central processing unit and a North Bridge chip is provided. Furthermore, this multi-chip structure and the memory are respectively disposed on the motherboard. In the multi-chip structure, the North Bridge chip is divided into a buffer area (112, 212 or 312) and an interconnection area (114, 214 or 314). The signal exchanged in the interconnection area (114, 214 or 314) is the first kind of signal output from the central processing unit. In other words, the transmission of signal between the central processing unit and the North Bridge chip is not going through the motherboard, but is directly transmitted through the electrical connection member of the multi-chip structure. In addition, the second kind of signal output from the central processing unit is transmitted to the motherboard purely through the buffer area (112, 212 or 312) of the North Bridge chip, and then the signal is transmitted to the memory through the circuits on the motherboard.

It should be noted that the application example of the foregoing central processing unit, North Bridge chip and the memory are used only as an illustration. The applications of the first chip (110, 210 or 310) and the second chip (120, 220 or 320) in the embodiment of the present invention do not have to be an assembly of a North Bridge chip together with a central processing unit.

In summary, the multi-chip structure of the present invention has the following advantages:

1. Because one of the chips in the multi-chip structure of the present invention can perform data processing with the interconnection area of the other one of the chips and transmit the electrical signals to the electronic device that is below the multi-chip structure, or one of the chips can directly transmit the electrical signals to the electronic device that is below the multi-chip structure through the buffer area of the other one of the chips, the number of interfaces in the multi-chip structure for transmitting electrical signals to the electronic device that is below the multi-chip structure is increased and the transmission efficiency of the multi-chip structure is improved.

2. Because the chips in the multi-chip structure of the present invention can be separately tested before assembling and electrically connecting the chips, the multi-chip structure has a higher yield and a lower production cost than that of the conventional system-on-chip structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-chip structure, comprising:
a first chip having a buffer area, an interconnection area, a redistribution conductive area and a first surface, wherein the buffer area is electrically insulated from the interconnection area, and the redistribution conductive area is disposed on the first surface;
a second chip disposed on the first surface; and
a plurality of conductive bumps disposed between the first surface and the second chip, wherein the second chip is electrically connected to the interconnection area through a first portion of the conductive bumps, and the second chip is electrically connected to the buffer area through a second portion of the conductive bumps and the redistribution conductive area;
wherein the second chip outputs a first kind of signal and a second kind of signal, the first kind of signal is input into the interconnection area through the first portion of the conductive bumps to participate in a processing operation of the first chip, and the second kind of signal is input into the buffer area through the second portion of the conductive bumps and the redistribution conductive area.

2. The multi-chip structure of claim 1, wherein the second kind of signal does not participate in the processing operation of the first chip.

3. The multi-chip structure of claim 1, wherein the buffer area comprises a plurality of conductive through holes.

4. The multi-chip structure of claim 1, wherein the redistribution conductive area comprises a plurality of redistribution conductive traces and the second portion of the conductive bumps are electrically connected to the buffer area through the redistribution conductive traces.

5. The multi-chip structure of claim 1, wherein in the interconnection area of the first chip are semiconductor devices and metal lines.

6. A multi-chip structure, comprising:
a first chip having a buffer area, an interconnection area and a first surface, wherein the buffer area is electrically insulated from the interconnection area;
a second chip disposed on the first surface; and
an electrical connection module disposed on the first chip and the second chip, wherein the second chip is electrically connected to the interconnection area through a first portion of the electrical connection module, and the second chip is electrically connected to the buffer area through a second portion of the electrical connection module;
wherein the second chip outputs a first kind of signal and a second kind of signal, the first kind of signal is input into the interconnection area through the first portion of the electrical connection module to participate in a processing operation of the first chip, and the second kind of signal is input into the buffer area through the second portion of electrical connection module.

7. The multi-chip structure of claim 6, wherein the second kind of signal does not participate in the processing operation of the first chip.

8. The multi-chip structure of claim 6, wherein the buffer area comprises a plurality of conductive through holes.

9. The multi-chip structure of claim 6, wherein the electrical connection module comprises a plurality of bonding wires such that the second chip is electrically connected to the interconnection area through a portion of the bonding wires and the second chip is electrically connected to the buffer area through another portion of the bonding wire.

10. The multi-chip structure of claim 6, wherein in the interconnection area of the first chip are semiconductor devices and metal lines.

11. The multi-chip structure of claim 6, wherein the electrical connection module comprises:
a flexible circuit board disposed on the first chip and the second chip;
a plurality of first conductive bumps disposed between the first chip and the flexible circuit board; and
a plurality of second conductive bumps disposed between the second chip and the flexible circuit board;
wherein the second chip is electrically connected to the interconnection area through a portion of the second conductive bumps, the flexible circuit board and a portion of the first conductive bumps, and the second chip is electrically connected to the buffer area through another portion of the second conductive bump, the flexible circuit board and another portion of the first conductive bumps.

12. The multi-chip structure of claim 6, wherein the first chip further has a redistribution conductive area disposed on the first surface, and the second chip is electrically connected to the buffer area through the second portion of the electrical connection module and the redistribution conductive area.

13. The multi-chip structure of claim 12, wherein the redistribution conductive area comprises a plurality of redistribution conductive traces, and the second portion of the electrical connection module is electrically connected to the buffer area through the redistribution conductive traces.

14. A multi-chip structure, comprising:
a first chip having a buffer area, an interconnection area and a first surface, wherein the buffer area is electrically insulated from the interconnection area; and
a second chip disposed on the first surface, wherein the second chip is electrically connected to the interconnection area and the buffer area;
wherein the second chip outputs a first kind of signal and a second kind of signal, the first kind of signal is input into the interconnection area to participate in a processing operation of the first chip, and the second kind of signal is input into the buffer area.

15. The multi-chip structure of claim 14, wherein the buffer area comprises a plurality of conductive through holes and wherein in the interconnection area of the first chip are semiconductor devices and metal lines.

16. The multi-chip structure of claim 14, wherein the first chip further has a redistribution conductive area disposed on the first surface.

17. The multi-chip structure of claim 16, wherein the redistribution conductive area comprises a plurality of redistribution conductive traces.

18. The multi-chip structure of claim 16, further comprising a plurality of conductive bumps disposed between the first surface of the first chip and the second chip, wherein the second chip is electrically connected to the interconnection area through a portion of the conductive bumps, and the second chip is electrically connected to the buffer area through another portion of the conductive bumps and the redistribution conductive area.

19. The multi-chip structure of claim 14, further comprising a plurality of bonding wires, wherein the second chip is electrically connected to the interconnection area through a portion of the bonding wires, and the second chip is electrically connected to the buffer area through another portion of the bonding wires.

20. The multi-chip structure of claim 14, further comprising:
a flexible circuit board disposed on the first chip and a the second chip;
a plurality of first conductive bumps disposed between the first chip and the flexible circuit board; and
a plurality of second conductive bumps, disposed between the second chip and the flexible circuit board, wherein the second chip is electrically connected to the interconnection area sequentially through a portion of the second conductive bumps, the flexible circuit board and a portion of the first bumps, and the second chip is electrically connected to the buffer area sequentially through another portion of the second conductive bumps, the flexible circuit board and another portion of the first conductive bumps.
